(19) United States
(12) Patent Application Publication
(10) Pub. No.: US 2025/0226043 A1
(43) Pub. Date: Jul. 10, 2025

(54) VALID WRITE OPERATION DETECTION FOR MEMORY DEVICES

(71) Applicant: Micron Technology, Inc., Boise, ID (US)

(72) Inventors: Melissa I. Uribe, El Dorado Hills, CA (US); Steffen Buch, Munich (DE); Aaron P. Boehm, Boise, ID (US); Scott E. Schaefer, Boise, ID (US)

(21) Appl. No.: 18/979,319

(22) Filed: Dec. 12, 2024

Related U.S. Application Data
(60) Provisional application No. 63/619,160, filed on Jan. 9, 2024.

(51) Int. Cl. G11C 29/18

(52) U.S. Cl. CPC G11C 29/18; G11C 2029/1802

(57) ABSTRACT

Methods, systems, and devices for valid write operation detection for memory devices are described. The described techniques provide for a memory system to set a flag in accordance with a status of an access operation. The memory system may receive a command to write data and may adjust a value of a mode register based on whether a write operation is valid. In some examples, the memory system may set the mode register value after successfully receiving, decoding, or completing the write command. In some other examples, if the memory system experiences a fault in receiving, decoding, or executing the write command, the memory system may refrain from setting the mode register value. A host device may poll the mode register to identify the validity of the write operation, and may perform one or more corrective actions if the write operation is invalid.

### CROSS REFERENCE

The present Application for Patent claims the benefit of U.S. Provisional Patent Application No. 63/619,160 by Uribe et al., entitled “VALID WRITE OPERATION DETECTION FOR MEMORY DEVICES,” filed Jan. 9, 2024, which is assigned to the assignee hereof, and which is expressly incorporated by reference in its entirety herein.

### TECHNICAL FIELD

The following relates to one or more systems for memory, including valid write operation detection for memory devices.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports valid write operation detection for memory devices in accordance with examples as disclosed herein.

FIG. 2 shows an example of an architecture that supports valid write operation detection for memory devices in accordance with examples as disclosed herein.

FIG. 3 shows an example of a process flow that supports valid write operation detection for memory devices in accordance with examples as disclosed herein.

FIG. 4 shows a block diagram of a memory system that supports valid write operation detection for memory devices in accordance with examples as disclosed herein.

FIG. 5 shows a block diagram of a host system that supports valid write operation detection for memory devices in accordance with examples as disclosed herein.

FIGS. 6 through 8 show flowcharts illustrating a method or methods that support valid write operation detection for memory devices in accordance with examples as disclosed herein.

### DETAILED DESCRIPTION

A memory system may be operable to perform various operations (e.g., applications) associated with storing and accessing data in one or more memory cells of the memory system. For example, the memory system may receive one or more access commands (e.g., from a host system) indicating for the memory system to store data to the one or more memory cells (e.g., a write command), obtain data stored to the one or more memory cells (e.g., a read command), or both. In some examples, the memory system may experience one or more faults when receiving or executing a command, such as failing to exit a mode to receive the command (e.g., a self-refresh mode), failing to decode the command, the command including invalid information (e.g., due to a package fault), or hardware of the memory system not operating properly, or any combination thereof, among other examples. Such faults may result in the memory system failing to receive, decode, or execute a command, and data associated with the command may be lost (e.g., if a write command is unsuccessful). Additionally, some error correction code (ECC) schemes may be unable to detect such faults, such as host inline ECC and link ECC schemes, which may identify whether stored data contains one or more errors (e.g., without detecting command execution faults). For example, if the memory system fails to execute a write command indicating new data, and old data remains stored to the one or more memory cells (e.g., not overwritten by the new data), the ECC schemes may detect whether errors are present in the old data without detecting the fault in execution of the command. In some cases, the memory system may support functional safety applications (e.g., automotive functional safety), which may be associated with one or more failure in time (FIT) constraints, among other constraints or related parameters. However, faults in receiving or executing access commands and failing to detect such faults may result in the memory system failing to satisfy FIT constraints, thereby limiting a performance of the memory system, among other challenges.

To indicate a validity of an operation associated with an access command, the memory system may set a flag in accordance with a status of the operation. For example, the memory system may receive a command to write data and may adjust a value, for example of a mode register or another location, based on whether a write operation (e.g., triggered by the write command) is valid. The memory system may adjust the value, such as the mode register value, from a first value (e.g., binary value ‘0’, which may be a default value) to a second value (e.g., binary value ‘1’) to indicate that the write operation is valid (e.g., that the write operation is received, decoded, determined to be or otherwise executed accurately, among other indications of validity). In some examples, the memory system may set the mode register value after successfully receiving and decoding the write command (e.g., but before a completion of performing the write operation) or may set the mode register value after successfully completing the write operation. If the memory system experiences a fault in receiving, decoding, or executing the write command, the memory system may refrain from setting the mode register value. Additionally, or alternatively, the memory system may signal the status of the write operation, for example to the host device, using one or more different methods such as via a pin (e.g., a decode status flag (DSF) pin, an alert pin, or some other type of pin), sending information indication or including the status of the write operation, or one or more other methods.

A host device may poll the mode register (or the pin or another location) to identify the validity of the write operation. For example, if the host device identifies that the mode register value is set to the second value (e.g., indicating the write operation is valid), the host device may reset the value of the mode register (e.g., to the default value) and may issue one or more subsequent access commands. Alternatively, if the host device identifies that the mode register value is set to the first value (e.g., the write operation is invalid), the host device may determine to perform one or more corrective actions. For example, the host device may issue a retransmission of the write command to the memory system, may pause an application associated with the write command, may disable an address space associated with the write command, or any combination thereof. Such techniques may improve detection of command execution failures, which may support the memory system satisfying FIT rate constraints and mitigating data loss.

In addition to applicability in memory systems as described herein, techniques for valid write operation detection for memory devices may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing failure rates for write commands due to faults in execution, which may reduce or mitigate latency associated with recovering lost or improperly stored data, among other benefits.

In addition to applicability in memory systems as described herein, techniques for valid write operation detection for memory devices may be generally implemented to support edge computing applications. Edge computing is a distributed computing paradigm that brings computation and data storage closer to the sources of data than traditional cloud services. As the use of edge computing to provide computing, storage, and networking services at locations that are geographically closer to end users increases, many devices and systems may benefit from improved processing, performance, and storage at edge devices. For example, increasing memory density, capacity, and processing power of edge devices may decrease a reliance on the devices to remote computing or devices, which may otherwise increase latency of operations performed at the devices. Implementing the techniques described herein may support edge computing techniques by reducing failure rates for write commands due to faults in execution at edge devices, among other benefits.

Features of the disclosure are illustrated and described in the context of systems and architectures. Features of the disclosure are further illustrated and described in the context of a process flow and flowcharts.

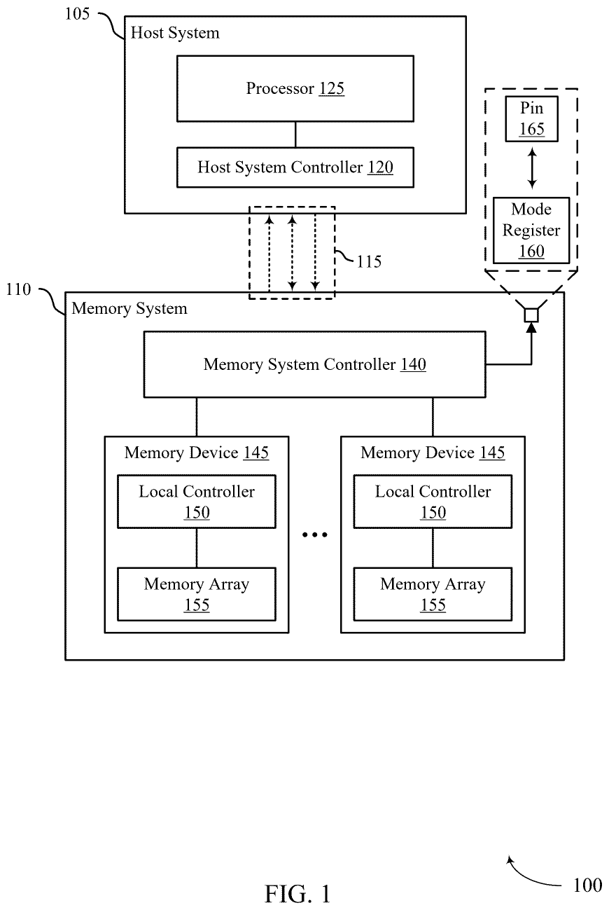

FIG. 1 illustrates an example of a system 100 that supports valid write operation detection for memory devices in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

In some examples of the system 100, the memory system 110 may experience one or more faults when receiving or executing a command (e.g., a write command) from the host system 105. For example, the memory system 110 may fail to exit a mode to receive the command (e.g., fail to exit self-refresh mode), fail to decode the command, the command may include invalid information (e.g., due to a package fault), hardware of the memory system 110 may not be operating properly, or any combination thereof, among other examples. Such faults may result in the memory system 110 failing to receive, decode, or execute a command, and data associated with the command may be lost (e.g., if a write command is unsuccessful). Some ECC schemes may be unable to detect such faults, such as host inline ECC and link ECC schemes, which may identify whether stored data contains one or more errors. In some cases, the memory system 110 may support functional safety applications (e.g., automotive functional safety), which may be associated with one or more FIT rate constraints. However, faults in receiving or executing access commands and failing to detect such faults may result in the memory system 110 failing to satisfy the FIT rate constraints, thereby limiting a performance of the memory system 110.

In some cases, the memory system 110 may set a flag to indicate a validity of an access operation. That is, the memory system controller 140 may be operable to adjust a value of the flag in accordance with a validity (or status) of the access operation, such as a write operation. For example, the memory system controller 140 may adjust a value of a mode register 160 from a first value (e.g., binary value ‘0’, which may be a default value) to a second value (e.g., binary value ‘1’) to indicate that the write operation is valid. In such examples, the memory system controller 140 may set the mode register 160 value after successfully receiving and decoding the write command or may set the mode register 160 value after successfully completing the write operation. As another example, the memory system controller 140 may refrain from setting the mode register 160 value if the memory system 110 experiences a fault in receiving, decoding, or executing the write command.

Additionally, or alternatively, in some examples, the memory system 110 may signal the status of the write operation (e.g., to the host system 105) via a pin 165, which may be an example of a DSF pin or an alert pin, or some other type of pin. The host system 105 may poll the mode register 160, the pin 165, or both to identify the validity of the write operation. In some examples, the value of the mode register 160 may be loaded to the pin 165. The host system 105 may be coupled with or otherwise have access to the mode register 160, the pin 165, or both. If the host system 105 identifies that the write operation is valid based on the mode register 160 and/or the pin 165, the host system 105 may reset the value of the mode register 160 (e.g., to the default value) and may issue one or more subsequent access commands to the memory system 110 (e.g., as part of normal operations). Alternatively, if the host system 105 identifies that the write operation is invalid, the host system 105 may determine to perform one or more corrective actions. For example, the host system 105 may issue a retransmission of the write command to the memory system 110, may pause an application associated with the write command, may disable an address space associated with the write command, or any combination thereof. Such techniques may improve detection of command execution failures, which may support the memory system 110 satisfying FIT rate constraints and mitigating data loss.

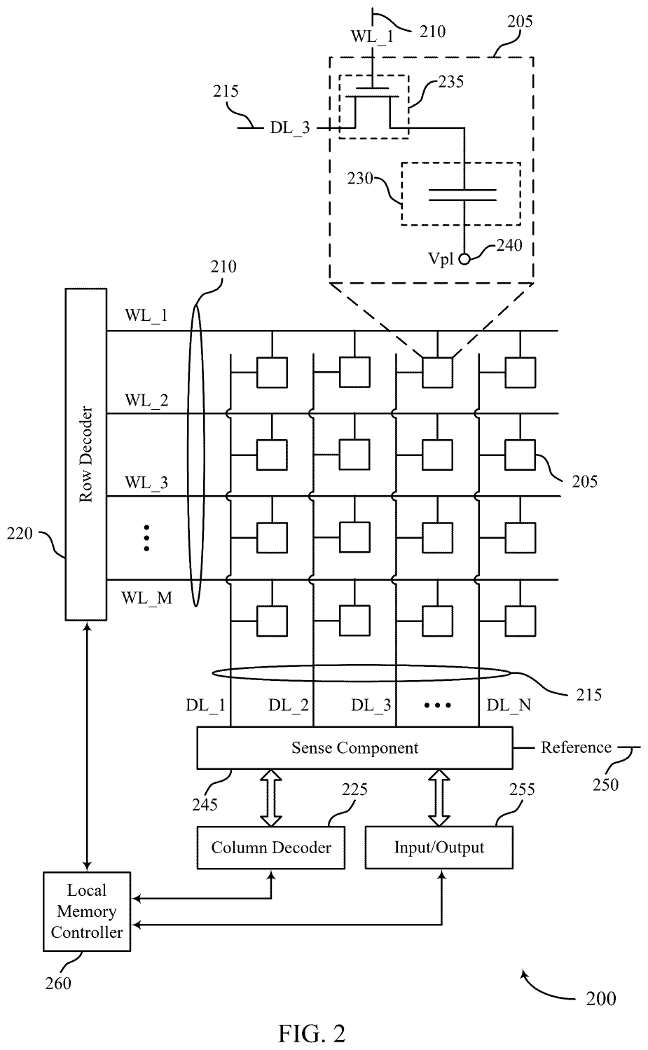

FIG. 2 illustrates an example of an architecture 200 (e.g., a memory architecture) that supports valid write operation detection for memory devices in accordance with examples as disclosed herein. The architecture 200 may be implemented in a memory system 110 or one or more components thereof (e.g., memory device 145). Aspects of the architecture 200 may be referred to as or implemented in a semiconductor component, such as a memory dic.

The architecture 200 includes memory cells 205 that are programmable to store information. In some examples, a memory cell 205 may be operable to store one bit of information at a time (e.g., a logic 0 or a logic 1). In some examples, a memory cell 205 (e.g., a multi-level memory cell) may be operable to store more than one bit of information at a time (e.g., a logic 00, logic 01, logic 10, a logic 11). Memory cells 205 may be arranged in an array, such as in a memory array 155.

In the example of architecture 200, a memory cell 205 may include a storage component, such as capacitor 230, and a selection component 235 (e.g., a cell selection component, a transistor). A capacitor 230 may be a dielectric capacitor or a ferroelectric capacitor. A node of the capacitor 230 may be coupled with a voltage source 240, which may be a cell plate reference voltage, such as Vpl, or may be a ground voltage, such as Vss. A charge stored by a memory cell 205 (e.g., by a capacitor 230) may be representative of a programmed state. Other memory architectures that support the techniques described herein may implement different types or arrangements of storage components and associated circuitry (e.g., with or without a selection component).

The architecture 200 may include various arrangements of access lines, such as word lines 210 and digit lines 215. An access line may be a conductive line that is coupled with a memory cell 205, and may be used to perform access operations on the memory cell 205. Word lines 210 may be referred to as row lines, and digit lines 215 may be referred to as column lines or bit lines, among other nomenclature. Memory cells 205 may be positioned at intersections of access lines, and an intersection may be referred to as an address of a memory cell 205.

In some architectures, a word line 210 may be coupled with a gate of a selection component 235 of a memory cell 205, and may be operable to control (e.g., switch, modulate a conductivity of) the selection component 235. A digit line 215 may be operable to couple a memory cell 205 with a sense component 245. In some architectures, a memory cell 205 (e.g., a capacitor 230) may be coupled with a digit line 215 during portions of an access operation. For example, a word line 210 and a selection component 235 of a memory cell 205 may be operable to couple or isolate a capacitor 230 of the memory cell 205 with a digit line 215.

Operations such as reading and writing may be performed on memory cells 205 by activating (e.g., applying a voltage to) access lines such as a word line 210 or a digit line 215. Accessing the memory cells 205 may be controlled through a row decoder 220, or a column decoder 225, or a combination thereof. For example, a row decoder 220 may receive a row address (e.g., from a local memory controller 260) and activate a word line 210 based on a received row address, and a column decoder 225 may receive a column address and activate a digit line 215 based on a received column address. Selecting or deselecting a memory cell 205 may include activating or deactivating a selection component 235 using a word line 210. For example, a capacitor 230 may be isolated from a digit line 215 when the selection component 235 is deactivated, and the capacitor 230 may be coupled with the digit line 215 when the selection component 235 is activated.

A sense component 245 may be operable to detect a state (e.g., a charge) stored by a capacitor 230 of a memory cell 205 and determine a logic state of the memory cell 205 based on the stored state. A sense component 245 may include one or more sense amplifiers to amplify or otherwise convert a signal resulting from accessing the memory cell 205. The sense component 245 may compare a signal detected from the memory cell 205 with a reference 250 (e.g., a reference voltage). The detected logic state of the memory cell 205 may be provided as an output of the sense component 245 (e.g., via an input/output 255), and may indicate the detected logic state to another component of a memory system 110 that implements the architecture 200.

The local memory controller 260 may control the accessing of memory cells 205 through the various components (e.g., a row decoder 220, a column decoder 225, a sense component 245), and may be an example of or otherwise included in a local controller 150, or a memory system controller 140, or both. In some examples, one or more of a row decoder 220, a column decoder 225, and a sense component 245 may be co-located with or included in the local memory controller 260. The local memory controller 260 may be operable to receive commands or data from one or more different controllers (e.g., a host system controller 120, a memory system controller 140), translate the commands or the data into information that can be used by the architecture 200, initiate or control one or more operations of the architecture 200, and communicate data from the architecture 200 to a host (e.g., a host system 105) based on performing the one or more operations.

The local memory controller 260 may be operable to perform one or more access operations on one or more memory cells 205 of the architecture 200. Examples of an access operation may include a write operation, a read operation, a refresh operation, a precharge operation, or an activate operation, among others. In some examples, an access operation may be performed by or otherwise coordinated by the local memory controller 260 in response to one or more access commands (e.g., from a host system 105). The local memory controller 260 may be operable to perform other access operations not listed here or other operations related to the operating of the architecture 200 that are not directly related to accessing the memory cells 205.

To support an access operation, a local memory controller 260 may identify a target memory cell 205 on which to perform the access operation, which may be associated with identifying a target word line 210 and a target digit line 215 coupled with the target memory cell 205 (e.g., an address of the target memory cell 205). The local memory controller 260 may control activating the target word line 210 and the target digit line 215 to access the target memory cell 205. During a write operation, the local memory controller 260 may control the application of a signal (e.g., a write pulse, a write voltage) to the target digit line 215 to store a specific state (e.g., a charge, in a capacitor 230) of the memory cell 205. The signal used as part of the write operation may include one or more voltage levels applied to the target memory cell 205 (e.g., via the target digit line 215) over one or more respective durations. During a read operation, the target memory cell 205 may transfer a signal (e.g., charge, voltage) to the sense component 245 based on activating the target word line 210 and the target digit line. The local memory controller 260 may activate the sense component 245 (e.g., initiate latching a sense amplifier of the sense component 245), which may include comparing the signal transferred from the memory cell 205 to a reference (e.g., the reference 250). Based on the comparison, the sense component 245 may determine a logic state that is stored on the memory cell 205.

In some examples of the architecture 200, a memory system may experience one or more faults when receiving or executing a command (e.g., a write command indicating data to be written to one or more memory cells 205). Such faults may result in the memory system failing to receive, decode, or execute a command, and data associated with the command may be lost (e.g., if a write command is unsuccessful). Additionally, some ECC schemes may be unable to detect such faults, such as host inline ECC and link ECC schemes, which may identify whether stored data contains one or more errors. In some cases, the memory system may support functional safety applications (e.g., automotive functional safety), which may be associated with one or more FIT rate constraints. However, faults in receiving or executing access commands and failing to detect such faults may result in the memory system failing to satisfy the FIT rate constraints, losing data, or both, thereby limiting a performance of the memory system.

In some cases, the memory system may set a flag to indicate a validity of an access operation. That is, the memory system controller may be operable to adjust a value of the flag in accordance with a validity (or status) of the access operation, such as a write operation. For example, controller (e.g., a memory system controller 140 or the local memory controller 260) may adjust a value of a mode register from a first value (e.g., binary ‘0’) to a second value (e.g., binary ‘1’) to indicate that the write operation is valid. In such examples, the controller may set the mode register value after successfully receiving and decoding the write command or may set the mode register value after successfully completing the write operation. As another example, the controller may refrain from setting the mode register value if the memory system experiences a fault in receiving, decoding, or executing the write command. In some examples, the memory system may signal the status of the write operation via a pin, which may be an example of a DSF pin or an alert pin.

A host system may poll the mode register (or the pin) to identify the validity of the write operation. For example, if the host system identifies that the mode register value is set to the second value (e.g., indicating the write operation is valid), the host system may reset the value of the mode register (e.g., to the default value) and may issue one or more subsequent access commands to the memory system 110 (e.g., as part of normal operations). Alternatively, if the host system identifies that the mode register value is the first value (e.g., indicating the write operation is invalid), the host system may determine to perform one or more corrective actions. For example, the host system may issue a retransmission of the write command to the memory system, may pause an application associated with the write command, may disable an address space associated with the write command, or any combination thereof. Such techniques may improve detection of command execution failures, which may support the memory system satisfying FIT rate constraints and mitigating data loss.

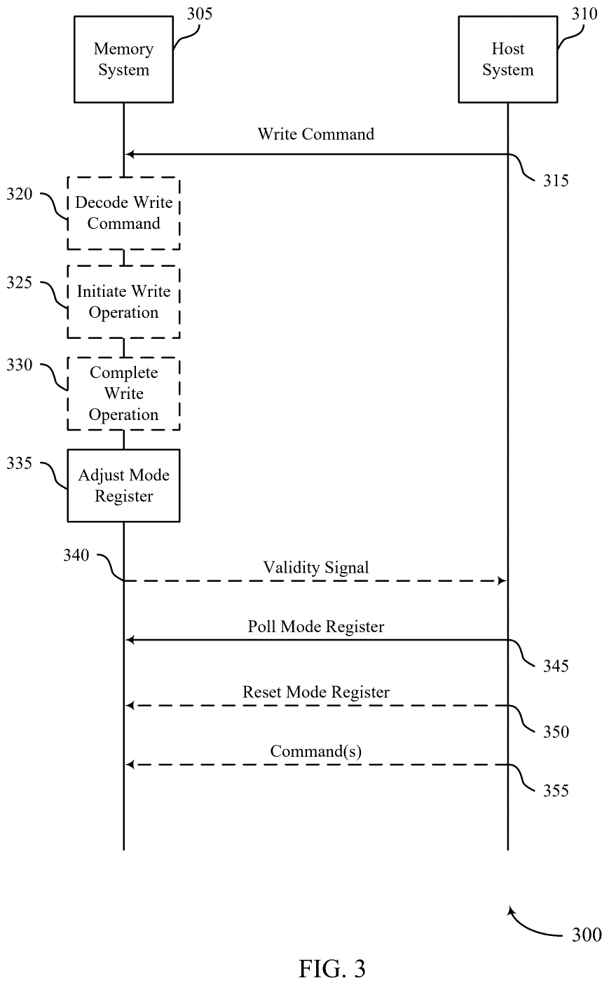

FIG. 3 shows an example of a process flow 300 that supports valid write operation detection for memory devices in accordance with examples as disclosed herein. The process flow 300 may implement, or be implemented by, one or more aspects of the system 100 and the architecture 200. For example, the process flow 300 may depict an example of signaling between a memory system 305 and a host system 310, which may be examples of corresponding aspects described with reference to FIG. 1. The process flow 300 may support the memory system 305 indicating a status of a write operation to write data to one or more memory cells of the memory system 305, which may be examples of memory cells 205 described with reference to FIG. 2. Alternative examples of the following may be implemented, where some processes are performed in a different order than described or are not performed. In some cases, processes may include additional features not mentioned below, or further processes may be added.

At 315, the memory system 305 may receive a write command from the host system 310. In some cases, the write command may indicate data to be written to one or more memory cells of the memory system 305.

At 320, in some examples, the memory system 305 may attempt to decode the write command based on receiving the write command (e.g., as part of or to support initiating a write operation). For example, the memory system 305 may identify the data to be written and an address space corresponding to the one or more memory cells based on decoding the write command, which may support the memory system 305 initiating a write operation associated with the write command. In some other examples, the memory system 305 may fail to successfully decode the write command (e.g., a command execution fault), which may prevent the memory system 305 from successfully executing the write command (e.g., invalidating the write operation).

At 325, in some examples, the memory system 305 may initiate the write operation to write the data to the one or more memory cells based on receiving and decoding the write command. In some cases, the memory system 305 may successfully initiate the write operation (e.g., the write operation is valid). In some other cases, the memory system 305 may experience a fault in receiving or decoding the command, which may result in the memory system 305 failing to successfully initiate the write operation (e.g., the write operation is invalid). For example, the command may be associated with a packet fault (e.g., the command indicates corrupted or incorrect data), an input buffer of the memory system 305 may be full or may otherwise fault, the memory system 305 may operate in a mode in which the memory system 305 is incapable of receiving and/or executing the command (e.g., a self-refresh mode), and the memory system 305 may fail to exit the mode to receive the command, hardware of the memory system 305 may fail to operate properly, or any combination thereof.

At 330, in some examples, the memory system 305 may complete the write operation (e.g., based on successfully decoding the write command and initiating the write operation). For example, the memory system 305 may successfully write the data to the one or more memory cells (e.g., validating the write operation). In some other examples, the memory system 305 may fail to successfully complete the write operation (e.g., a command execution fault) and may not write the data to the one or more memory cells (e.g., invalidating the write operation). If the memory system 305 does not successfully complete the write operation, the data to be written may be lost (e.g., old data may remain stored to the one or more memory cells).

At 335, the memory system 305 may adjust a value of a mode register according to a status of the write operation. For example, if the memory system 305 successfully executes and completes the write operation at 330, the memory system 305 may adjust the mode register from a first value (e.g., binary value ‘0’, which may be a default value) to a second value (e.g., binary value ‘1’), where the second value may indicate that the write operation is valid. In some cases, the memory system 305 may adjust the mode register value at various stages of the write operation. As a first example, the memory system 305 may adjust the value of the mode register to the second value based on (e.g., after, upon, or in response to) successfully decoding the write command and initiating the write operation (e.g., at operations 320 and 325). As a second example, the memory system 305 may adjust the value of the mode register to the second value based on successfully completing the write operation (e.g., at operation 330). The stage of the memory access operation which triggers the memory system 305 to adjust the mode register value (e.g., decoding and initiating the operation or completing the operation) may be based on a target robustness of the fault detection scheme, a location of the fault detection circuitry, or both. Additionally, or alternatively, the memory system 305 may be operable to switch the trigger for adjusting the mode register value (e.g., dynamically) between various stages of the write operation.

In some examples, if the memory system 305 fails to successfully execute the write operation, the memory system 305 may refrain from adjusting the value of the mode register. For example, if the memory system 305 fails to decode and initiate or fails to complete the write operation (e.g., based on the trigger to set the mode register value), the memory system 305 may refrain from adjusting the value of the mode register (e.g., the value of the mode register may remain at the default value). The default value of the mode register may indicate that the write operation is invalid (e.g., incomplete).

At 340, the memory system 305 may transmit a validity signal to the host system 310 indicating a validity of a write operation. In some cases, to transmit the validity signal, the memory system 305 may load the value of the mode register to a pin (e.g., bias the pin according to the mode register value) configured to indicate the validity of the write operation. For example, if the memory system 305 identifies that the write operation is valid, the memory system 305 may set the mode register from the first value to the second value and may bias the pin from a first voltage to a second voltage (e.g., the second voltage indicating that the write operation is valid). Additionally, or alternatively, the memory system 305 may bias the pin to the second voltage after identifying that the write operation is valid (e.g., without adjusting the value of the mode register). In some examples, the pin may be an example of a DSF pin (e.g., a direct media interface (DMI) I/O pin used during a read operation as DSF+ to output a status or flag a failure before data bursts begin) or an alert pin (e.g., a double data rate 4 (DDR4) and/or a low-power DDR 6 (LPDDR6) alert pin that is output to indicate a failure status), or some other type of pin that is coupled with the memory system 305 and the host system 310.

By adjusting the value of the mode register, biasing the pin, or both according to the validity (or status) of the write command, the memory system 305 may improve detection of faults in command execution, which may support the memory system 305 satisfying one or more FIT rate constraints (e.g., a unit representing failure rates and how many failures occur every 10⁹ hours). For example, the memory system 305 may be operable to perform a functional safety application, such as an automotive functional safety application, which may be associated with a FIT rate constraint, such as <0.4 FIT undetected (e.g., for a stand-alone DRAM device in automotive safety integrity level (ASIL) D). In some examples, one or more ECC schemes implemented by the memory system 305, such as host inline ECC and link ECC, may be unsuitable to detect faults in command execution (e.g., faults in decoding, initiating, or completing a command). For example, such ECC schemes may be configured to detect whether values stored to a memory array are correct (e.g., detect data corruption). In such examples, if the memory system 305 fails to execute a write command, the memory system 305 may fail to overwrite old data with the new data indicated in the write command. However, if the old data does not contain errors (e.g., is not corrupted), the ECC schemes may detect no errors in the data and the host system 310 may remain unaware of the command execution fault. Thus, the memory system 305 may improve command execution fault detection by indicating the validity of an access operation via the value of the mode register and/or the pin, which may support the memory system 305 satisfying FIT rate constraints for one or more applications (such as automotive functional safety applications).

At 345, the host system 310 may poll the mode register based on transmitting the write command. In some cases, the host system 310 may identify the value of the mode register based on polling the mode register, which may indicate the validity of the write operation at the memory system 305. In some examples, the host system 310 may determine, based on the value of the mode register, whether to issue a command to the memory system 305 to perform a retransmission of the write command or to perform a subsequent access command. For example, if the host system 310 identifies that the write command was successfully executed (e.g., based on the mode register being set to the second value) and the host system 310 does not have a subsequent access command queued for transmission to the memory system 305, the host system 310 may refrain from issuing another command to the memory system 305. Additionally, or alternatively, the host system 310 may poll the pin and may identify the validity of the write operation according to the value of the pin (e.g., the DSF pin or alert pin) based on the validity signal received from the memory system 305 (e.g., at 340).

At 350, in some examples, the host system 310 may transmit, to the memory system 305, a command to reset the value of the mode register. For example, the host system 310 may determine, based on polling the mode register, that the value of the mode register (which may be referred to as a first value, the second value, a ‘set’ mode register value, binary value ‘1’, or the like) indicates that the write operation is valid. In such examples, the host system 310 may transmit the command to reset the value of the mode register back to a default value (e.g., from the ‘set’ value to an ‘unset’ value) based on determining that the value of the mode register indicates that the write operation is valid. Such techniques may support the memory system 305 indicating a validity of subsequent access operations.

At 355, in some examples, the host system 310 may transmit, to the memory system 305, one or more commands based on the value of the mode register, the validity signal indicated via the pin, or both. As a first example, the host system 310 may determine to transmit the subsequent access command to the memory system 305 based on the value of the mode register indicating that the write operation is valid. In such examples, the subsequent access command may be an example of a read command that indicates the data to be read from the one or more memory cells or may be an example of a second write command that indicates second data to be written to the one or more memory cells (or one or more second memory cells of the memory system 305). In some cases, if the subsequent access command is a second write command, the memory system 305 may indicate a validity of a second write operation associated with the second write command via the mode register value (or the pin) according to operations 320 through 340. For example, the memory system 305 may refrain from adjusting the value of the mode register from the first value to the second value based on a failure to decode or complete (e.g., according to the trigger to set the mode register value) the second write command, where the first value may indicate that the second write operation is invalid.

As a second example, the host system 310 may determine to transmit a retransmission of the write command to the memory system 305 based on the value of the mode register indicating that the write operation is invalid. In some cases, the memory system 305 may receive the retransmission of the write command, may reinitiate the write operation (e.g., attempt to execute the write command again), and may adjust the mode register value according to a validity of the write operation (e.g., refraining from adjusting the mode register value if the write operation is still unsuccessful or adjusting the mode register value to the second value is the write operation is successful). In some examples, the host system 310 may transmit an erase command to erase the data from the one or more memory cells prior to issuing the retransmission of the write command (e.g., to clear the data in advance of the retransmission of the write command). In some examples, the host system 310 may continue to retransmit the write command until the write operation at the memory system 305 is successful (e.g., the host system 310 identifies the mode register value as the second value).

As a third example, the host system 310 may determine to disable an address space associated with the one or more memory cells based on the write operation being invalid. For example, the host system 310 may identify that write operations at the address space are more likely to be unsuccessful (e.g., the address space is associated with a threshold quantity of command execution faults, a greater quantity of command execution faults compared to one or more other address spaces of the memory system, or both), and may transmit a command to the memory system 305 indicating to disable the address space. In some examples, if the host system 310 determines to issue a retransmission of the write command, the retransmission of the write command may indicate the data to be written to one or more second memory cells of the memory system that are different that the one or more first memory cells (e.g., associated with a different address space).

As a fourth example, the host system 310 may pause execution of an application associated with the write command based on the mode register value indicating that the write operation is invalid. For example, the host system 310 may transmit a command to the memory system 305 indicating for the memory system 305 to pause (e.g., temporarily terminate) an application associated with the write command, which may support the host system 310 performing one or more corrective actions, such as retransmitting the write command, disabling an address space associated with the write command, or both, among other examples.

Such techniques may improve detection of command execution failures, which may support the memory system 305 satisfying FIT rate constraints and mitigating data loss, among other examples.

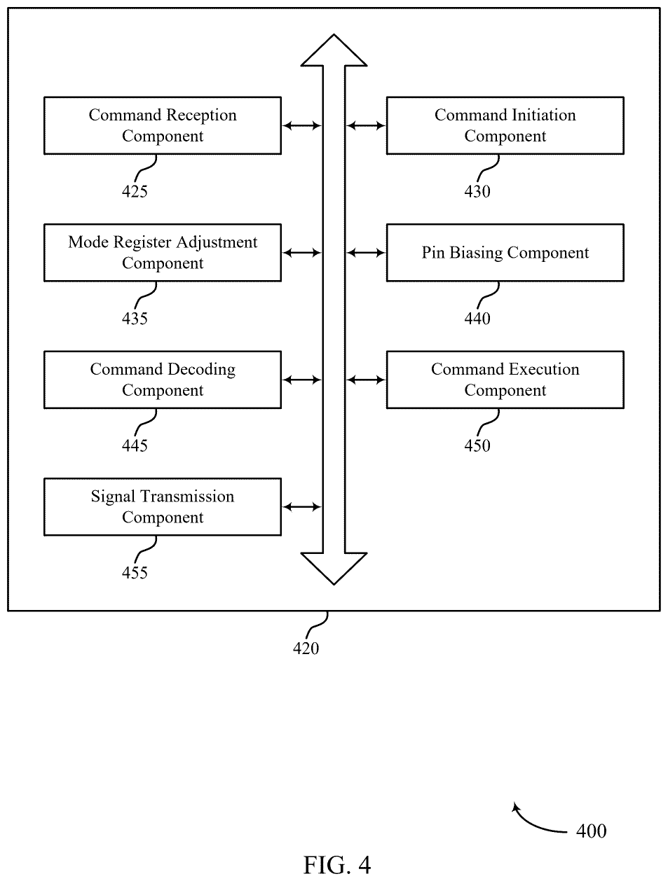

FIG. 4 shows a block diagram 400 of a memory system 420 that supports valid write operation detection for memory devices in accordance with examples as disclosed herein. The memory system 420 may be an example of aspects of a memory system as described with reference to FIGS. 1 through 3. The memory system 420, or various components thereof, may be an example of means for performing various aspects of valid write operation detection for memory devices as described herein. For example, the memory system 420 may include a command reception component 425, a command initiation component 430, a mode register adjustment component 435, a pin biasing component 440, a command decoding component 445, a command execution component 450, a signal transmission component 455, or any combination thereof. Each of these components, or components of subcomponents thereof (e.g., one or more processors, one or more memories), may communicate, directly or indirectly, with one another (e.g., via one or more buses).

The command reception component 425 may be configured as or otherwise support a means for receiving a write command that indicates data to be written for one or more memory cells of a memory system. The command initiation component 430 may be configured as or otherwise support a means for initiating a write operation to write the data to the one or more memory cells based at least in part on the write command. The mode register adjustment component 435 may be configured as or otherwise support a means for adjusting a value of a mode register from a first value to a second value based at least in part on initiating the write operation, where the value of the mode register indicates a validity of the write operation.

In some examples, the command decoding component 445 may be configured as or otherwise support a means for decoding the write command based at least in part on receiving the write command. In some examples, the mode register adjustment component 435 may be configured as or otherwise support a means for adjusting the value of the mode register to the second value based at least in part on decoding the write command and initiating the write operation, where the second value indicates that the write operation is valid.

In some examples, the command execution component 450 may be configured as or otherwise support a means for completing the write operation based at least in part on initiating the write operation. In some examples, the mode register adjustment component 435 may be configured as or otherwise support a means for adjusting the value of the mode register to the second value based at least in part on completing the write operation, where the second value indicates that the write operation is valid.

In some examples, the command reception component 425 may be configured as or otherwise support a means for receiving, after adjusting the mode register back to the first value, a second write command that indicates second data to be written to one or more second memory cells of the memory system. In some examples, the mode register adjustment component 435 may be configured as or otherwise support a means for refraining from adjusting the value of the mode register from the first value to the second value based at least in part on a failure to decode the second write command, where the first value indicates that the write operation is invalid.

In some examples, the command reception component 425 may be configured as or otherwise support a means for receiving, based at least in part on refraining from adjusting the value of the mode register, a retransmission of the second write command that indicates the second data to be written to the one or more second memory cells of the memory system.

In some examples, the signal transmission component 455 may be configured as or otherwise support a means for transmitting, to a host device via a pin and based at least in part on adjusting the value of the mode register to the second value, a signal to indicate the validity of the write operation.

In some examples, the pin includes a decode status flag or an alert pin.

In some examples, the first value includes a first binary value of the mode register and the second value includes a second binary value of the mode register.

In some examples, the command reception component 425 may be configured as or otherwise support a means for receiving a write command that indicates data to be written for one or more memory cells of a memory system. In some examples, the command initiation component 430 may be configured as or otherwise support a means for initiating a write operation to write the data to the one or more memory cells based at least in part on the write command. The pin biasing component 440 may be configured as or otherwise support a means for biasing a pin from a first value to a second value based at least in part on initiating the write operation, where a value of the pin indicates a validity of the write operation.

In some examples, the command decoding component 445 may be configured as or otherwise support a means for decoding the write command based at least in part on receiving the write command. In some examples, the pin biasing component 440 may be configured as or otherwise support a means for biasing the pin to the second value based at least in part on decoding and initiating the write operation, where the second value indicates that the write operation is valid.

In some examples, the pin includes a decode status flag or an alert pin.

In some examples, the described functionality of the memory system 420, or various components thereof, may be supported by or may refer to at least a portion of at least one processor, where such at least one processor may include one or more processing clements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

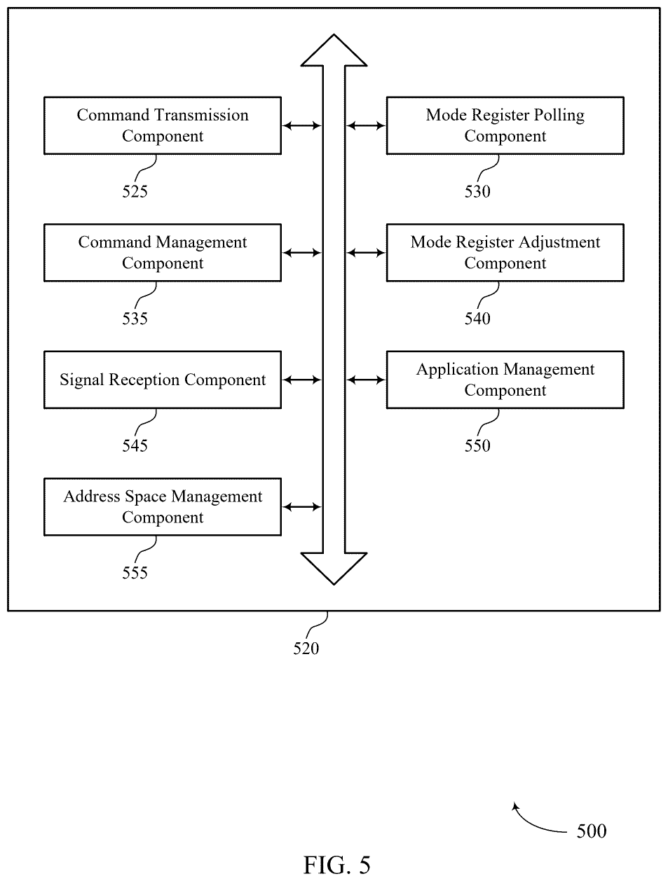

FIG. 5 shows a block diagram 500 of a host system 520 that supports valid write operation detection for memory devices in accordance with examples as disclosed herein. The host system 520 may be an example of aspects of a host system as described with reference to FIGS. 1 through 3. The host system 520, or various components thereof, may be an example of means for performing various aspects of valid write operation detection for memory devices as described herein. For example, the host system 520 may include a command transmission component 525, a mode register polling component 530, a command management component 535, a mode register adjustment component 540, a signal reception component 545, an application management component 550, an address space management component 555, or any combination thereof. Each of these components, or components of subcomponents thereof (e.g., one or more processors, one or more memories), may communicate, directly or indirectly, with one another (e.g., via one or more buses).

The command transmission component 525 may be configured as or otherwise support a means for transmitting, from a host system, a write command that indicates data to be written to one or more memory cells of a memory system. The mode register polling component 530 may be configured as or otherwise support a means for polling a mode register of a memory system based at least in part on the write command, where a value of the mode register indicates a validity of a write operation at the memory system. The command management component 535 may be configured as or otherwise support a means for determining, based at least in part on the value of the mode register, whether to issue a command to the memory system to perform a retransmission of the write command or a subsequent access command.

In some examples, the mode register polling component 530 may be configured as or otherwise support a means for determining, based at least in part on polling the mode register, that the value of the mode register includes a first value that indicates the write operation is valid. In some examples, the mode register adjustment component 540 may be configured as or otherwise support a means for resetting the value of the mode register from the first value to a second value based at least in part on determining that the value of the mode register includes the first value.

In some examples, to support determining whether to issue the command to the memory system, the command management component 535 may be configured as or otherwise support a means for determining to transmit the subsequent access command to the memory system based at least in part on the value of the mode register indicating that the write operation is valid, where the subsequent access command includes a read command that indicates the data to be read from the one or more memory cells or a second write command that indicates second data to be written to the one or more memory cells.

In some examples, to support determining whether to issue the command to the memory system, the command management component 535 may be configured as or otherwise support a means for determining to transmit the retransmission of the write command to the memory system based at least in part on the value of the mode register including a second value that indicates the write operation is invalid.

In some examples, the command transmission component 525 may be configured as or otherwise support a means for transmitting an erase command to erase the data from the one or more memory cells based at least in part on the write operation being invalid. In some examples, the command transmission component 525 may be configured as or otherwise support a means for transmitting the retransmission of the write command based at least in part on the erase command.

In some examples, the application management component 550 may be configured as or otherwise support a means for pausing execution of an application associated with the write command based at least in part on the write operation being invalid.

In some examples, the address space management component 555 may be configured as or otherwise support a means for disabling an address space associated with the one or more memory cells based at least in part on the write operation being invalid, where the retransmission of the write command indicates the data to be written to one or more second memory cells of the memory system that are different than the one or more memory cells based at least in part on disabling the address space.

In some examples, the signal reception component 545 may be configured as or otherwise support a means for receiving, via a pin, a signal to indicate the validity of the write operation, where determining whether to issue the command is based at least in part on receiving the signal.

In some examples, the pin includes a decode status flag or an alert pin.

In some examples, the described functionality of the host system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the host system 520, or various components thereof, may be implemented at least in part by instructions (e.g., stored in memory, non-transitory computer-readable medium) executable by such at least one processor.

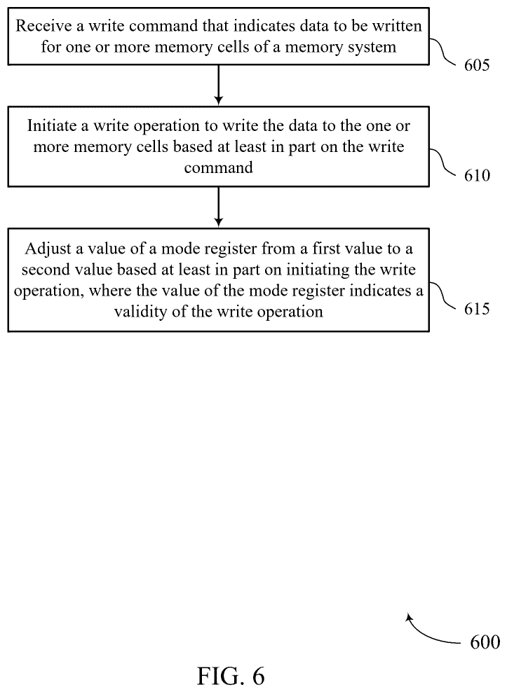

FIG. 6 shows a flowchart illustrating a method 600 that supports valid write operation detection for memory devices in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 605, the method may include receiving a write command that indicates data to be written for one or more memory cells of a memory system. In some examples, aspects of the operations of 605 may be performed by a command reception component 425 as described with reference to FIG. 4.

At 610, the method may include initiating a write operation to write the data to the one or more memory cells based at least in part on the write command. In some examples, aspects of the operations of 610 may be performed by a command initiation component 430 as described with reference to FIG. 4.

At 615, the method may include adjusting a value of a mode register from a first value to a second value based at least in part on initiating the write operation, where the value of the mode register indicates a validity of the write operation. In some examples, aspects of the operations of 615 may be performed by a mode register adjustment component 435 as described with reference to FIG. 4.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a write command that indicates data to be written for one or more memory cells of a memory system; initiating a write operation to write the data to the one or more memory cells based at least in part on the write command; and adjusting a value of a mode register from a first value to a second value based at least in part on initiating the write operation, where the value of the mode register indicates a validity of the write operation.

Aspect 2: The method, apparatus, or non-transitory computer-readable medium of aspect 1, further including operations, features, circuitry, logic, means, or instructions, or any combination thereof for decoding the write command based at least in part on receiving the write command, where adjusting the value of the mode register includes and adjusting the value of the mode register to the second value based at least in part on decoding the write command and initiating the write operation, where the second value indicates that the write operation is valid.

Aspect 3: The method, apparatus, or non-transitory computer-readable medium of any of aspects 1 through 2, further including operations, features, circuitry, logic, means, or instructions, or any combination thereof for completing the write operation based at least in part on initiating the write operation, where adjusting the value of the mode register includes and adjusting the value of the mode register to the second value based at least in part on completing the write operation, where the second value indicates that the write operation is valid.

Aspect 4: The method, apparatus, or non-transitory computer-readable medium of any of aspects 1 through 3, further including operations, features, circuitry, logic, means, or instructions, or any combination thereof for receiving, after adjusting the mode register back to the first value, a second write command that indicates second data to be written to one or more second memory cells of the memory system and refraining from adjusting the value of the mode register from the first value to the second value based at least in part on a failure to decode the second write command, where the first value indicates that the write operation is invalid.

Aspect 5: The method, apparatus, or non-transitory computer-readable medium of aspect 4, further including operations, features, circuitry, logic, means, or instructions, or any combination thereof for receiving, based at least in part on refraining from adjusting the value of the mode register, a retransmission of the second write command that indicates the second data to be written to the one or more second memory cells of the memory system.

Aspect 6: The method, apparatus, or non-transitory computer-readable medium of any of aspects 1 through 5, further including operations, features, circuitry, logic, means, or instructions, or any combination thereof for transmitting, to a host device via a pin and based at least in part on adjusting the value of the mode register to the second value, a signal to indicate the validity of the write operation.

Aspect 7: The method, apparatus, or non-transitory computer-readable medium of aspect 6, where the pin includes a decode status flag or an alert pin.

Aspect 8: The method, apparatus, or non-transitory computer-readable medium of any of aspects 1 through 7, where the first value includes a first binary value of the mode register and the second value includes a second binary value of the mode register.

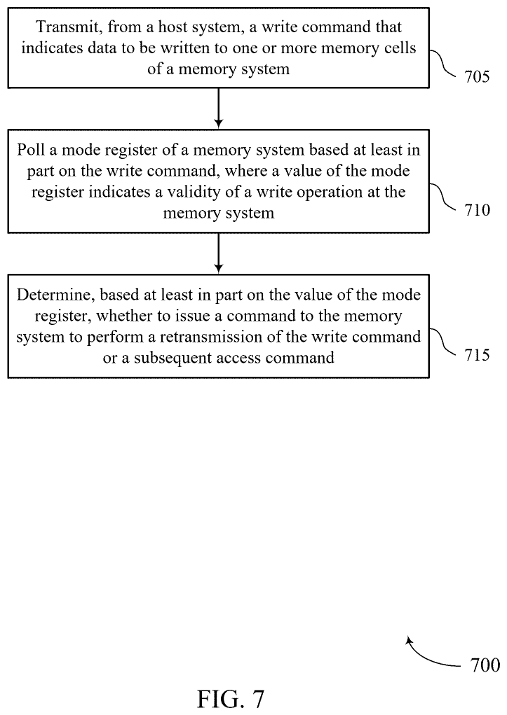

FIG. 7 shows a flowchart illustrating a method 700 that supports valid write operation detection for memory devices in accordance with examples as disclosed herein. The operations of method 700 may be implemented by a host system or its components as described herein. For example, the operations of method 700 may be performed by a host system as described with reference to FIGS. 1 through 3 and 5. In some examples, a host system may execute a set of instructions to control the functional elements of the device to perform the described functions. Additionally, or alternatively, the host system may perform aspects of the described functions using special-purpose hardware.

At 705, the method may include transmitting, from a host system, a write command that indicates data to be written to one or more memory cells of a memory system. In some examples, aspects of the operations of 705 may be performed by a command transmission component 525 as described with reference to FIG. 5.

At 710, the method may include polling a mode register of a memory system based at least in part on the write command, where a value of the mode register indicates a validity of a write operation at the memory system. In some examples, aspects of the operations of 710 may be performed by a mode register polling component 530 as described with reference to FIG. 5.

At 715, the method may include determining, based at least in part on the value of the mode register, whether to issue a command to the memory system to perform a retransmission of the write command or a subsequent access command. In some examples, aspects of the operations of 715 may be performed by a command management component 535 as described with reference to FIG. 5.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 9: A method, apparatus, or non-transitory computer-readable medium including operations, features, circuitry, logic, means, or instructions, or any combination thereof for transmitting, from a host system, a write command that indicates data to be written to one or more memory cells of a memory system; polling a mode register of a memory system based at least in part on the write command, where a value of the mode register indicates a validity of a write operation at the memory system; and determining, based at least in part on the value of the mode register, whether to issue a command to the memory system to perform a retransmission of the write command or a subsequent access command.

Aspect 10: The method, apparatus, or non-transitory computer-readable medium of aspect 9, further including operations, features, circuitry, logic, means, or instructions, or any combination thereof for determining, based at least in part on polling the mode register, that the value of the mode register includes a first value that indicates the write operation is valid and resetting the value of the mode register from the first value to a second value based at least in part on determining that the value of the mode register includes the first value.

Aspect 11: The method, apparatus, or non-transitory computer-readable medium of any of aspects 9 through 10, where determining whether to issue the command to the memory system includes operations, features, circuitry, logic, means, or instructions, or any combination thereof for determining to transmit the subsequent access command to the memory system based at least in part on the value of the mode register indicating that the write operation is valid, where the subsequent access command includes a read command that indicates the data to be read from the one or more memory cells or a second write command that indicates second data to be written to the one or more memory cells.

Aspect 12: The method, apparatus, or non-transitory computer-readable medium of any of aspects 9 through 11, where determining whether to issue the command to the memory system includes operations, features, circuitry, logic, means, or instructions, or any combination thereof for determining to transmit the retransmission of the write command to the memory system based at least in part on the value of the mode register including a second value that indicates the write operation is invalid.

Aspect 13: The method, apparatus, or non-transitory computer-readable medium of aspect 12, further including operations, features, circuitry, logic, means, or instructions, or any combination thereof for transmitting an crase command to erase the data from the one or more memory cells based at least in part on the write operation being invalid and transmitting the retransmission of the write command based at least in part on the erase command.

Aspect 14: The method, apparatus, or non-transitory computer-readable medium of any of aspects 12 through 13, further including operations, features, circuitry, logic, means, or instructions, or any combination thereof for pausing execution of an application associated with the write command based at least in part on the write operation being invalid.

Aspect 15: The method, apparatus, or non-transitory computer-readable medium of any of aspects 12 through 14, further including operations, features, circuitry, logic, means, or instructions, or any combination thereof for disabling an address space associated with the one or more memory cells based at least in part on the write operation being invalid, where the retransmission of the write command indicates the data to be written to one or more second memory cells of the memory system that are different than the one or more memory cells based at least in part on disabling the address space.

Aspect 16: The method, apparatus, or non-transitory computer-readable medium of any of aspects 9 through 15, further including operations, features, circuitry, logic, means, or instructions, or any combination thereof for receiving, via a pin, a signal to indicate the validity of the write operation, where determining whether to issue the command is based at least in part on receiving the signal.

Aspect 17: The method, apparatus, or non-transitory computer-readable medium of aspect 16, where the pin includes a decode status flag or an alert pin.

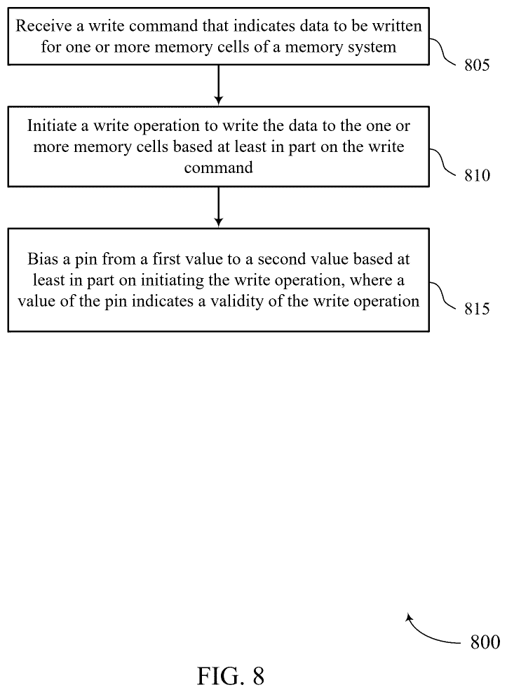

FIG. 8 shows a flowchart illustrating a method 800 that supports valid write operation detection for memory devices in accordance with examples as disclosed herein. The operations of method 800 may be implemented by a memory system or its components as described herein. For example, the operations of method 800 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 805, the method may include receiving a write command that indicates data to be written for one or more memory cells of a memory system. In some examples, aspects of the operations of 805 may be performed by a command reception component 425 as described with reference to FIG. 4.

At 810, the method may include initiating a write operation to write the data to the one or more memory cells based at least in part on the write command. In some examples, aspects of the operations of 810 may be performed by a command initiation component 430 as described with reference to FIG. 4.

At 815, the method may include biasing a pin from a first value to a second value based at least in part on initiating the write operation, where a value of the pin indicates a validity of the write operation. In some examples, aspects of the operations of 815 may be performed by a pin biasing component 440 as described with reference to FIG. 4.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 18: A method, apparatus, or non-transitory computer-readable medium including operations, features, circuitry, logic, means, or instructions, or any combination thereof for receiving a write command that indicates data to be written for one or more memory cells of a memory system; initiating a write operation to write the data to the one or more memory cells based at least in part on the write command; and biasing a pin from a first value to a second value based at least in part on initiating the write operation, where a value of the pin indicates a validity of the write operation.

Aspect 19: The method, apparatus, or non-transitory computer-readable medium of aspect 18, further including operations, features, circuitry, logic, means, or instructions, or any combination thereof for decoding the write command based at least in part on receiving the write command, where biasing the pin includes and biasing the pin to the second value based at least in part on decoding and initiating the write operation, where the second value indicates that the write operation is valid.

Aspect 20: The method, apparatus, or non-transitory computer-readable medium of any of aspects 18 through 19, further including operations, features, circuitry, logic, means, or instructions, or any combination thereof for completing the write operation based at least in part on initiating the write operation, and biasing the pin to the second value based at least in part on completing the write operation, wherein the second value indicates that the write operation is valid.

Aspect 21: The method, apparatus, or non-transitory computer-readable medium of any of aspects 18 through 20, further including operations, features, circuitry, logic, means, or instructions, or any combination thereof for receiving, after adjusting the pin back to the first value, a second write command that indicates second data to be written to one or more second memory cells of the memory system, and refraining from adjusting the bias of the pin from the first value to the second value based at least in part on a failure to decode the second write command, wherein the first value indicates that the write operation is invalid.

Aspect 22: The method, apparatus, or non-transitory computer-readable medium of aspect 21, further including operations, features, circuitry, logic, means, or instructions, or any combination thereof for receiving, based at least in part on refraining from adjusting the bias of the pin, a retransmission of the second write command that indicates the second data to be written to the one or more second memory cells of the memory system.

Aspect 23: The method, apparatus, or non-transitory computer-readable medium of any of aspects 18 through 22, where the pin includes a decode status flag or an alert pin.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which that can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed hercin.

What is claimed is:

1. An apparatus, comprising:
processing circuitry associated with one or more memory devices and configured to cause the apparatus to:
receive a write command that indicates data to be written for one or more memory cells of a memory system;
initiate a write operation to write the data to the one or more memory cells based at least in part on the write command; and
adjust a value of a mode register from a first value to a second value based at least in part on initiating the write operation, wherein the value of the mode register indicates a validity of the write operation.

2. The apparatus of claim 1, wherein the processing circuitry is further configured to cause the apparatus to:
decode the write command based at least in part on receiving the write command, wherein, to adjust the value of the mode register, the processing circuitry is configured to cause the apparatus to:
adjust the value of the mode register to the second value based at least in part on decoding the write command and initiating the write operation, wherein the second value indicates that the write operation is valid.

3. The apparatus of claim 1, wherein the processing circuitry is further configured to cause the apparatus to:
complete the write operation based at least in part on initiating the write operation, wherein, to adjust the value of the mode register, the processing circuitry is configured to cause the apparatus to:
adjust the value of the mode register to the second value based at least in part on completing the write operation, wherein the second value indicates that the write operation is valid.

4. The apparatus of claim 1, wherein the processing circuitry is further configured to cause the apparatus to:
receive, after adjusting the mode register back to the first value, a second write command that indicates second data to be written to one or more second memory cells of the memory system; and
refrain from adjusting the value of the mode register from the first value to the second value based at least in part on a failure to decode the second write command, wherein the first value indicates that the write operation is invalid.

5. The apparatus of claim 4, wherein the processing circuitry is further configured to cause the apparatus to:
receive, based at least in part on refraining from adjusting the value of the mode register, a retransmission of the second write command that indicates the second data to be written to the one or more second memory cells of the memory system.

6. The apparatus of claim 1, wherein the processing circuitry is further configured to cause the apparatus to:
transmit, to a host device via a pin and based at least in part on adjusting the value of the mode register to the second value, a signal to indicate the validity of the write operation.

7. The apparatus of claim 6, wherein the pin comprises a decode status flag or an alert pin.

8. The apparatus of claim 1, wherein the first value comprises a first binary value of the mode register and the second value comprises a second binary value of the mode register.

9. An apparatus, comprising:
processing circuitry associated with one or more memory devices and configured to cause the apparatus to:
transmit, from a host system, a write command that indicates data to be written to one or more memory cells of a memory system;
poll a mode register of a memory system based at least in part on the write command, wherein a value of the mode register indicates a validity of a write operation at the memory system; and
determine, based at least in part on the value of the mode register, whether to issue a command to the memory system to perform a retransmission of the write command or a subsequent access command.

10. The apparatus of claim 9, wherein the processing circuitry is further configured to cause the apparatus to:
determine, based at least in part on polling the mode register, that the value of the mode register comprises a first value that indicates the write operation is valid; and
reset the value of the mode register from the first value to a second value based at least in part on determining that the value of the mode register comprises the first value.

11. The apparatus of claim 9, wherein, to determine whether to issue the command to the memory system, the processing circuitry is configured to cause the apparatus to:
determine to transmit the subsequent access command to the memory system based at least in part on the value of the mode register indicating that the write operation is valid, wherein the subsequent access command comprises a read command that indicates the data to be read from the one or more memory cells or a second write command that indicates second data to be written to the one or more memory cells.

12. The apparatus of claim 9, wherein, to determine whether to issue the command to the memory system, the processing circuitry is configured to cause the apparatus to:
determine to transmit the retransmission of the write command to the memory system based at least in part on the value of the mode register comprising a second value that indicates the write operation is invalid.

13. The apparatus of claim 12, wherein the processing circuitry is further configured to cause the apparatus to:
transmit an erase command to erase the data from the one or more memory cells based at least in part on the write operation being invalid; and
transmit the retransmission of the write command based at least in part on the erase command.

14. The apparatus of claim 12, wherein the processing circuitry is further configured to cause the apparatus to:
pause execution of an application associated with the write command based at least in part on the write operation being invalid.

15. The apparatus of claim 12, wherein the processing circuitry is further configured to cause the apparatus to:
disable an address space associated with the one or more memory cells based at least in part on the write operation being invalid, wherein the retransmission of the write command indicates the data to be written to one or more second memory cells of the memory system that are different than the one or more memory cells based at least in part on disabling the address space.

16. The apparatus of claim 9, wherein the processing circuitry is further configured to cause the apparatus to:
receive, via a pin, a signal to indicate the validity of the write operation, wherein determining whether to issue the command is based at least in part on receiving the signal.

17. The apparatus of claim 16, wherein the pin comprises a decode status flag or an alert pin.

18. An apparatus, comprising:
processing circuitry associated with one or more memory devices and configured to cause the apparatus to:
receive a write command that indicates data to be written for one or more memory cells of a memory system;
initiate a write operation to write the data to the one or more memory cells based at least in part on the write command; and
bias a pin from a first value to a second value based at least in part on initiating the write operation, wherein a value of the pin indicates a validity of the write operation.

19. The apparatus of claim 18, wherein the processing circuitry is further configured to cause the apparatus to:
decode the write command based at least in part on receiving the write command, wherein, to bias the pin, the processing circuitry is configured to cause the apparatus to:
bias the pin to the second value based at least in part on decoding and initiating the write operation, wherein the second value indicates that the write operation is valid.

20. The apparatus of claim 18, wherein the processing circuitry is further configured to cause the apparatus to:
complete the write operation based at least in part on initiating the write operation, wherein, to bias the pin, the processing circuitry is configured to cause the apparatus to:
bias the pin to the second value based at least in part on completing the write operation, wherein the second value indicates that the write operation is valid.

21. The apparatus of claim 18, wherein the processing circuitry is further configured to cause the apparatus to:
receive, after adjusting the pin back to the first value, a second write command that indicates second data to be written to one or more second memory cells of the memory system; and
refrain from adjusting the bias of the pin from the first value to the second value based at least in part on a failure to decode the second write command, wherein the first value indicates that the write operation is invalid.

22. The apparatus of claim 21, wherein the processing circuitry is further configured to cause the apparatus to:
receive, based at least in part on refraining from adjusting the bias of the pin, a retransmission of the second write command that indicates the second data to be written to the one or more second memory cells of the memory system.

23. The apparatus of claim 18, wherein the pin comprises a decode status flag or an alert pin.
